(19) United States
(12) Patent Application Publication
(10) Pub. No.: US 2026/0293028 A1
(43) Pub. Date: Sep. 24, 2026

(54) ELECTRONIC SUPPLY DEVICE FOR ELECTRICALLY CONNECTING AN ELECTRICAL CONSUMER AND ELECTRONIC CONSUMER DEVICE

(71) Applicant: H4X e.U., Graz (AT)

(72) Inventor: Andreas HIERZER, Graz (AT)

(73) Assignee: H4X e.U., Graz (AT)

(21) Appl. No.: 19/573,142

(22) Filed: Mar. 20, 2026

(30) Foreign Application Priority Data
Mar. 20, 2025 (AT) A50190/2025

(51) Int. Cl. H05K 7/14; H02M 7/00; H05K 1/181

(52) U.S. Cl. CPC H05K 7/14322; H02M 7/003; H05K 1/181; H05K 7/14327; H05K 2201/09027; H05K 2201/10022; H05K 2201/10106; H05K 2201/10318

(57) ABSTRACT

An electronic supply device for electrically connecting an electrical consumer includes a housing having an electrical circuit board device, the housing being mountable on an external electrical conductor device, and the electrical circuit board device being electrically connectable to the external electrical conductor device by a conductor contact device, the electrical circuit board device including a circuit board resistor; an external electrical contact device having: first, second, and third external contacts first, second, and third counter contacts of the electrical consumer, the third counter contact being in an electrical connection with a predetermined consumer resistor of the electrical consumer that, in the contact position and together with the at least one circuit board resistor, forms a voltage divider through which an electrical power specific to the relevant electrical consumer can be provided to the electrical consumer via the first counter contact and via the second counter contact.

### TECHNICAL FIELD OF THE INVENTION

The invention relates to an electronic supply device for electrically connecting an electrical consumer and to an electronic consumer device.

### TECHNICAL BACKGROUND

In conventional lighting systems or consumers which require connection to a stationary power source, the position of the contacts or terminals of the power source is usually fixed at a particular location and a particular consumer and therefore limited. Typically, wiring is routed to a contact position or mounting position of the consumer or light, the connection between the cable and the contact point allowing only few, if any, degrees of freedom of movement or positional variation. The position of the contact point is therefore usually predetermined at a particular location or a particular region by the construction of the lighting system or consumer.

With a view to greater flexibility in the positioning of the electrical contact point and preferably also in the mounting position of the consumer or lighting system, it therefore appears desirable to provide an electronic supply device, for electrically connecting an electrical consumer, and an electronic consumer device which is distinguished by an improved and more flexible interface between the electrical conductor and the electrical consumer, in particular by a possibility of more flexible and freely selectable positioning thereof on a mounting surface of the electrical conductor.

The document WO 2023/016661 A1 describes a power adapter for connecting a consumer to an electrical conductor.

### SUMMARY OF THE INVENTION

One of the objects of the invention is to find solutions, for an electronic supply device for electrically connecting an electrical consumer, by means of which a contact and mounting position on a surface of an electrical conductor device can be flexibly and freely selectable and by means of which electrical connection of different consumer types can be made possible.

This and further objects are achieved by an electronic supply device for electrically connecting an electrical consumer having the features of claim 1 and by an electronic consumer device having the features of claim 17.

In a first aspect of the invention, the electronic supply device for electrically connecting an electrical consumer comprises a housing having a fastening device and an electrical circuit board device, the housing being mechanically mountable, in a contact position of the housing, by means of the fastening device, on a surface of an external electrical conductor device or on a surface covering an external electrical conductor device, and the electrical circuit board device being electrically connectable to the external electrical conductor device in the contact position by means of a conductor contact device which is movably arranged in and/or with the housing, the electrical circuit board device comprising at least one circuit board resistor. The electronic supply device further comprises an external electrical contact device which is arranged on the housing and which can be contacted by counter contacts of the electrical consumer, the external electrical contact device further comprising a first external contact which can be electrically contacted with a first counter contact of the electrical consumer; a second external contact which can be electrically contacted with a second counter contact of the electrical consumer; and a third external contact which can be electrically contacted with a third counter contact of the electrical consumer, the third counter contact being in an electrical connection with a predetermined consumer resistor of the electrical consumer, the predetermined consumer resistor, in the contact position, forming together with the at least one circuit board resistor a voltage divider through which an electrical power specific to the relevant electrical consumer can be provided to the electrical consumer via the first counter contact and via the second counter contact.

The electronic supply device can advantageously form an electrical contact interface between the external electrical conductor device and the electrical consumer. For this purpose, the electronic supply device can be electrically connected to the external electrical conductor device and mechanically fastened to a surface of the external electrical conductor device itself or to a surface covering the external electrical conductor device. For example, a side face or lower face of the electronic supply device housing may rest against said surface and fix the housing to this surface and/or to the external electrical conductor device by means of fasteners. These fasteners may also establish the electrical contact and may for example be formed by said conductor contact device and/or fastening device.

The external electrical contact device may be present on an outside of the housing of the electronic supply device, for example on an upper face of the housing, which may be opposite a face of the housing having the fastening device, for example a lower face of the housing. In this way, the electronic supply device can establish electrical and mechanical contact with the external electrical conductor device in a first direction and establish mechanical and electrical contact with the electrical consumer in a second direction, which may be counter to the first direction.

The three external contacts may be an earth and a positive and negative contact.

In electrical contact with the counter contacts, the predetermined consumer resistor of the electrical consumer can act as a voltage divider together with the at least one circuit board resistor. This can therefore be correspondingly different for each consumer, the same electronic supply device now being usable for different consumers without having to be removed from the external electrical conductor device and replaced. For this purpose, the circuit board resistor may preferably also comprise more than one resistor for the bridge circuit. In accordance with the resulting voltage divider effect, the power drop across the consumer can be adjusted in accordance with its specific power without the electronic supply device having to be replaced, since the corresponding voltage division makes it possible for the electronic components of the supply device to continue operating even if the specific power of the consumer differs from one consumer to another.

The fastening device may be movable in or together with the housing, in particular between a contact position of the housing and a transport position of the housing (for example a two-part housing). The transport position may be appropriate and applicable in every case of this type where the housing, and thus the electronic supply device, is not in mechanical and electrical contact with the external electrical conductor device. For this purpose, the conductor contact device may be partially or completely retracted into the housing in the transport position, making it possible to prevent mechanical contact of the conductor contact device with other objects outside the housing or at least significantly to reduce the risk of this. However, the conductor contact device can still be mechanically and electrically connected to the circuit board device (in both positions of the housing). Advantageously, the housing may comprise a first part and a second part, the first part of the housing being insertable into the second part thereof (or vice versa) so as to assume the contact position, and the conductor contact device, for example comprising pins, being pushable out of openings on the lower face of the housing, which may form the base of the first part. The housing, in the contact position and with the conductor contact device extended, can then be pressed through the surface of the external electrical conductor device, and the conductor contact device, for example the pins, can thus be mechanically and electrically connected to the electrical conductor paths of the external electrical conductor device. To increase the retaining force between the housing and the surface at the external electrical conductor device, one or more magnets may be arranged in the housing so as to hold the housing against the surface of the external electrical conductor device.

The housing may further have a locking mechanism which, in the transport position, can project radially or laterally (perpendicular to the displacement direction of the two parts of the housing into one another) from at least one of the parts of the housing and can prevent the two housing parts from sliding into one another. The locking mechanism may comprise one or more spring-loaded buttons, which can be pressed into the interior of the housing part on which they are arranged, and subsequently the two housing parts can slide into one another, since the at least one button then no longer protrudes (laterally) beyond the outer edges of the two housing parts, and thus no longer blocks them from sliding into one another, and the housing can be slid into the contact position.

In a first aspect of the invention, the electronic consumer device comprises an electronic supply device according to the invention, which can be electrically and mechanically connected via a surface to an external electrical conductor device, the electronic consumer device further comprising an electrical consumer, which, via the electronic supply device, can be electrically connected to the external electrical conductor device and operated.

The electrical consumer device, comprising a consumer, may advantageously be supplied with a particular current/voltage required for its operation by the electronic supply device. Through the voltage divider, which can be formed by connecting the at least one circuit board resistor to the consumer resistor with appropriately contacted external contacts and counter contacts, the consumer can be supplied with a voltage or voltage range tailored for it to be able to operate at a predetermined specific power output.

Advantageous embodiments and developments will be apparent from the further dependent claims and from the description with reference to the drawings.

In a development of the electronic supply device, the first external contact and/or the second external contact and/or the third external contact are formed as a ring contact.

In a development of the electronic supply device, the first external contact forms a circular surface, and the second external contact and third external contact extend around the first external contact as spaced-apart concentric annular surfaces.

As a result of an embodiment as annular surfaces or a circular surface, the contacting via the respective counter contacts can advantageously take place in such a way that the housings of the supply device and consumer can be rotated through 360°and the contact guidance of the counter contact along the associated annular surface or circular surface is advantageously not interrupted. For this purpose, the counter contacts may advantageously be arranged in such a way that they are positioned opposite one another when the respective circular or annular surfaces of the two housings of the supply device and consumer are placed opposing one another, and in such a way that, when the housing of the supply device is inserted into the contact recess of the housing of the consumer, a rotation of the housings with respect to one another can only occur in such a way (the contact recess may advantageously limit radial or lateral displacement of the housings with respect to one another in such a way that, during movement and rotation, the counter contacts do not leave the surfaces of the external contacts, and the paths of the movement of the counter contacts during rotation of the housings with respect to one another do not completely, but may possibly partially, leave the surfaces of the external contacts) that the mutual (mechanical and electrical) contact between the counter contacts and the external contacts is maintained. The rotation may for example take place about an axis which passes through the centre point of the central circular surface of the first external contact.

In a development of the electronic supply device, the conductor contact device comprises at least two pins as electrical contacts, which are extended from the housing in its contact position and can be brought into mechanical and electrical contact with the surface of the external electrical conductor device or with the surface covering the external electrical conductor device.

In a development of the electronic supply device, the pins can penetrate the surface of the external electrical conductor device or the surface covering the external electrical conductor device, and different pins can be contacted with electrical conductors of different polarity, in particular by the pins.

In a development of the electronic supply device, the external electrical contact device is arranged on an externally accessible upper face of the housing, which is opposite a lower face of the housing, the fastening device being arranged and/or the conductor contact device being extendable on the lower face.

The conductor contact device may also comprise more than two pins, for example five. By means of the pins, conductors of the external conductor device can be mechanically and electrically contacted, at least two pins being able to contact those (sub-)conductors of the conductor device through which an oppositely polarised current flows. As a result of the pointed shape of the pins, both the surface on the conductor device and the conductor device itself can be penetrated or reached when the housing of the supply device is placed on the external conductor device or its surface with a particular force from the user.

The external conductor installation may for example be a wall component and/or ceiling component for a room, which may be applied to or integrated into a wall and/or ceiling or may itself form the wall and/or ceiling, it being possible for the surface to serve as rendering of the wall and/or ceiling and to be of a particular colour. Said surface can also be repainted during renovation of the room.

In a development of the electronic supply device, the electronic supply device and the circuit board device comprise at least one rectifier, by means of which a current received from the external electrical conductor device via the conductor contact device can be applied to the first external contact and second external contact with different polarities from one another. By means of the rectifier, a direct current of a particular direct voltage, for example 48 V, can be applied to the two external contacts (first and second, or else in another arrangement). The current and thus the specific power of the consumer can then be achieved by way of the correspondingly provided voltage divider.

In a development of the electronic supply device, the housing with the fastening device is set up to be arranged on a planar surface which forms or covers the external electrical conductor device.

In a development of the electronic supply device, the electrical circuit board device comprises at least two flat circuit boards, which are spaced apart from one another and extend centred and parallel along an axis and are interconnected via a contact device or plug device.

To save space, two or even more circuit boards may be interconnected via plugs and arranged mutually parallel in the housing of the supply device. It may also be possible to place components with high heat generation on a different circuit board from components highly sensitive to heat.

In a development of the electronic supply device, the three external contacts are arranged on a face of the second circuit board facing away from the first circuit board.

The external contacts may be arranged on the second circuit board and face away from the first circuit board when the two circuit boards are plugged together. Furthermore, the external contacts may also extend out of the housing or at least be arranged in a recess of the housing and be accessible (exposed) from the outside/from the environment.

In a development of the electronic supply device, the electrical circuit board device comprises a control device, which can receive and interpret a wirelessly transmitted control signal and via which operation of the electrical consumer can be controlled.

In this way, the power of the consumer or the current to be applied to it can be controlled or switched off; for example, the consumer in the form of a light can be dimmed, the emission colour can be adjusted or the like.

In a development of the electronic supply device, the circuit board resistor comprises a first resistor and a second resistor, which, in contact with the predetermined consumer resistor, form a voltage divider.

The voltage divider may be configured as a bridge circuit or in another form if the consumer resistor is connected to the circuit board via the external contacts.

In a development of the electronic supply device, the rectifier is arranged on a face of the first circuit board facing the second circuit board.

To reduce the space required for assembly within the housing, even the region between the two circuit boards may be used so as to exclude the rectifier component.

In a development of the electronic supply device, the electrical circuit board device comprises an LED driver device by means of which the specific electrical power can be detected and provided.

In a development of the electronic supply device, the electrical circuit board device comprises a hot-plug protector.

In a development of the electronic supply device, the electronic supply device comprises a signal light which is arranged on the housing and via which electrical contact with the external electrical conductor device can be indicated.

In a development of the electronic consumer device, the electrical consumer comprises a housing having a mounting region, via which the electrical consumer can be placed and magnetically fixed on the surface of the external electrical conductor device or on a surface covering the external electrical conductor device, and has in the mounting region a contact recess into which the electronic supply device can be inserted, and, when the supply device is inserted, the counter contacts of the electrical consumer extend from the housing of the electrical consumer into the contact recess, and, when the electrical consumer is inserted, the counter contacts can be electrically contacted with the respectively associated external contacts of the electronic supply device.

The electrical consumer may thus also be mounted on the same surface of the external electrical conductor device as the electronic supply device itself. For this purpose, the electrical consumer may itself comprise a housing with the mounting region. The housing of the electronic supply device can be inserted into the contact recess, advantageously being covered by the contact recess and the housing of the consumer. The counter contacts can be placed on the corresponding external contacts. For example, the counter contacts can be pressed from a rest position into a contact position, in other words counter to a spring tension towards the housing of the consumer (into said housing), when the housing of the consumer is placed over the housing of the supply device. When the housings are removed from one another, the spring tension of the individual counter contacts can extend them back into a rest position. The counter contacts may for example be pin contacts, which may have at their tips an electrical contact surface, via which the pin contact can bring electronics of the consumer into electrical contact with the associated external contact of the supply device. The pin contacts may have rounded electrical contact surfaces at their tips.

In a development of the electronic consumer device, the contact recess and the housing of the electrical consumer are circular and, when enclosed, are orientated concentrically with one another and spaced apart in a planar manner with respect to the surface, or interlock in a flush manner, the housing of the electrical consumer being rotatable through 360° around the housing of the electronic supply device and about the concentric axis.

In a development of the electronic consumer device, the counter contacts of the electrical consumer comprise spring-loaded pin contacts.

In a development of the electronic consumer device, the electrical consumer comprises a dimmable or non-dimmable light.

In a development of the electronic consumer device, the electrical consumer comprises a charger or a display device or a power source for a further consumer.

Furthermore, the consumer may simply be just a socket, for example in USB or USB-C or other standards. Furthermore, the consumer may be a power connector, a DC jack or a light source or display device (display, picture frame or the like) or a charger.

By way of the voltage divider, consumers having different specifications can advantageously be supplied with their specific power uptake from the two first external contacts. The advantage here is that different consumers having different specific power uptakes can be operated using the same supply device. Users do not need different plugs for different consumers, but rather can position the same plugs on the surface as desired and attach different consumers to/via them. This advantageously increases the flexibility of possible arrangements and prevents damage to the consumers, or at least significantly reduces the risk of damage. Instead of using magnets in the housing of the supply device, it is also possible simply to exploit the friction between the surfaces and the pins during penetration into the surface and into the conductor.

In the wall or ceiling or the mounting to the wall or ceiling, conductors of the conductor device may be configured as differently polarised electrical conductor paths (for example 48V), the contact pins of the conductor contact device penetrating the fastening surface of the conductor device in the contact position and always being in electrical contact with at least two differently polarised conductor paths.

The rectifier may be attached to the face of the first circuit board facing the second circuit board or vice versa. The circuit board resistors may be arranged on the first or on the second circuit board.

An LED driver arranged on the second circuit board or on the first circuit board can provide the specific power uptake of the consumer via the first and second external contact.

The consumer may be configured freely as a dimmable or non-dimmable light, which can be supplied with its specific power uptake by the circuit board kit (at any selectable dimming level if it is dimmable).

In the consumer contact position, the consumer may be detachably and rotatably fastened to the supply device, or to the fastening surface so as to overlap the supply device. In other words, it is also possible for the electrical consumer to comprise a housing having a mounting region, via which the electrical consumer can be placed and magnetically fixed on the housing of the supply device, and counter contacts of the electrical consumer may extend out of the mounting region and a contact recess present therein, from the housing of the electrical consumer to the respectively associated external contacts of the electronic supply device.

A signal LED on the outside of the supply device, for example arranged on the first circuit board, may light up when there is an electrical connection to the conductors.

As example values, a voltage of 3V may be applied to the consumer at 400 mA, with R1=400 kilohms, R2=50,000 ohms, and R3=30,000 ohms. For constant R2 and R3, a current of 300 mA and a voltage of 2.25V may be set at the consumer at R1=560 kilohms. Other orders of magnitude are also achievable, for example R1=1.84 megaohms at a current of 100 mA and a voltage of 0.75V. The above embodiments and developments can be combined with one another as desired, within reason. Further possible embodiments, developments and implementations of the invention also include combinations not explicitly mentioned of features of the invention described above or below with reference to the example embodiments. In particular, those skilled in the art will also add individual aspects as improvements or additions to each basic form of the present invention.

### BRIEF DESCRIPTION OF THE DRAWINGS

The present invention will be explained in greater detail in the following with reference to the example embodiments shown in the schematic drawings, in which:

FIG. 1a is a schematic drawing of an electronic supply device according to an example embodiment of the present invention.

FIG. 1b shows the electronic supply device of FIG. 1a obliquely from its lower face.

FIG. 2 is a schematic drawing of the electrical circuit board device of the electronic supply device according to an example embodiment of the present invention.

FIG. 3 is a top view of a second circuit board of the electrical circuit board device.

FIG. 4 is a schematic view of an electronic consumer device according to an example embodiment of the present invention.

FIG. 5 is a schematic sectional drawing of the electrical circuit board device of the electronic supply device with the first circuit board and second circuit board plugged together.

FIG. 6 is a schematic drawing of the electronic consumer device in an external view according to an example embodiment of the present invention.

The accompanying drawings are intended to provide further understanding of the embodiments of the invention. They illustrate embodiments and serve, in conjunction with the description, to explain principles and concepts of the invention. Other embodiments and many of the stated advantages will be apparent upon reference to the drawings. Elements of the drawings are not necessarily shown to scale with one another. Directional terminology such as “top”, “bottom”, “left”, “right”, “above”, “below”, “horizontal”, “vertical”, “front”, “back” and the like is used purely for explanatory purposes and is not intended to limit the generality to specific embodiments shown in the drawings.

In the drawings, like, functionally equivalent and equivalently acting elements, features and components are provided with like reference signs unless stated otherwise.

### DETAILED DESCRIPTION OF EXAMPLE EMBODIMENTS

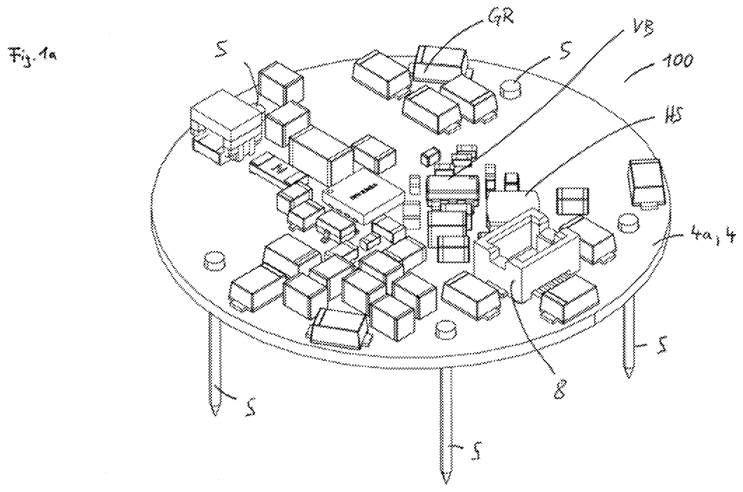

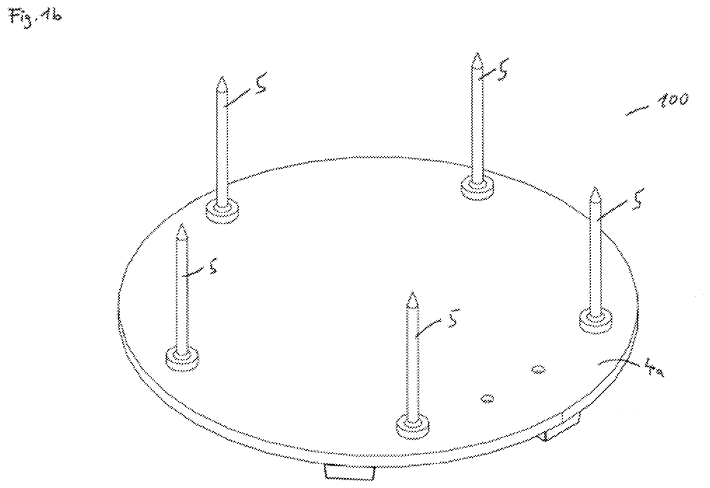

FIG. 1a is a schematic drawing of an electronic supply device according to an example embodiment of the present invention.

The electronic supply device 100 is shown in FIG. 1a along with a first circuit board 4a of the circuit board device 4. On its upper face, various components of the circuit board device 4 and supply device 100 are schematically shown. This arrangement may also vary. The first circuit board 4a is circular and has a plug receiver for a plug device 8, for example in the form of a female counterpart which can be connected to a corresponding counterpart on the second circuit board (not shown), and the two circuit boards can be interconnected, for example when arranged one above the other. Pins of the conductor contact device 5 may be attached to the first circuit board 4a and may extend away from the first circuit board 4a in a first direction. The housing of the supply device is not shown in FIG. 1a.

FIG. 1a further shows example arrangements of components, which may be a rectifier GR, a hot-plug protector HS, a supply VB for a Bluetooth transmission and/or others.

FIG. 1b shows the electronic supply device of FIG. 1a obliquely from its lower face.

The pins of the conductor contact device 5 may extend perpendicularly away from the first circuit board 4a. In the contact position of the housing (not shown) of the supply device 100, these pins 5 can then be pushed through openings in the housing and out of the housing.

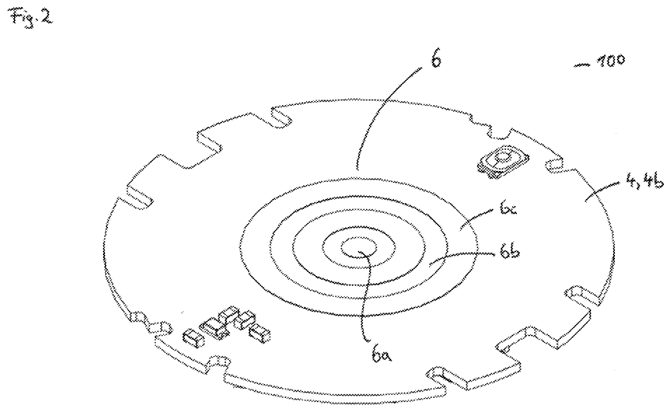

FIG. 2 is a schematic drawing of the electrical circuit board device of the electronic supply device according to an example embodiment of the present invention.

The circuit board device 4 may comprise a second circuit board 4b, which is shown in FIG. 2 from a second direction arranged counter to the first direction of FIG. 1a. The second circuit board, and thus the supply device 100, may comprise an external electrical contact device 6, which can be contacted by counter contacts of the electrical consumer (not shown), the external electrical contact device 6 comprising a first external contact 6a, which can be electrically contacted with a first counter contact (not shown) of the electrical consumer; further comprising a second external contact 6b, which can be electrically contacted with a second counter contact (not shown) of the electrical consumer; and comprising a third external contact 6c, which can be electrically contacted with a third counter contact (not shown) of the electrical consumer.

In the embodiment of FIG. 2, the first external contact 6a may be formed as a circular surface, and the second external contact 6b and the third external contact 6c may enclose the first external contact 6a as spaced-apart concentric annular surfaces. The widths of the two annular surfaces may be the same as or different from one another, and may be matched to or advantageously be greater than the width of the counter contacts. The centre point of the circular surface may be coincident with an axis of rotation about which a housing of the consumer can be rotated around the housing of the supply device. The second circuit board 4b may further have particular notches or recesses at the edge of its circular shape for fixing in a housing of the supply device.

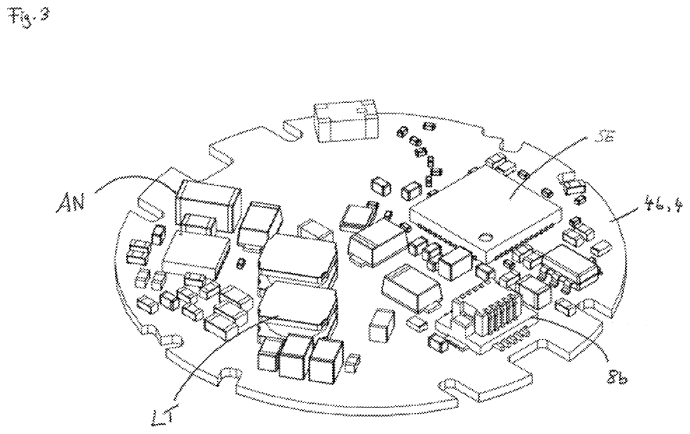

FIG. 3 is a top view of the second circuit board of the electrical circuit board device.

The upper face of the second circuit board 4b may be configured in accordance with the view in FIG. 2, with the external contacts shown therein, while its lower face may have further electronic components, as shown in FIG. 3, for example a control device SE which can receive and interpret a wirelessly transmitted control signal, for example Bluetooth, and via which operation of the electrical consumer can be controlled. This control device SE and/or the second circuit board 4b may also comprise an LED driver device LT.

The counterpart 8b of the plug device 8, which can be concealed with the female counterpart from FIG. 1a and via which a particular distance between the two circuit boards can be set, is now also shown on the lower face of the second circuit board 4b. For wireless transmission, an antenna path AN with associated components may also be implemented.

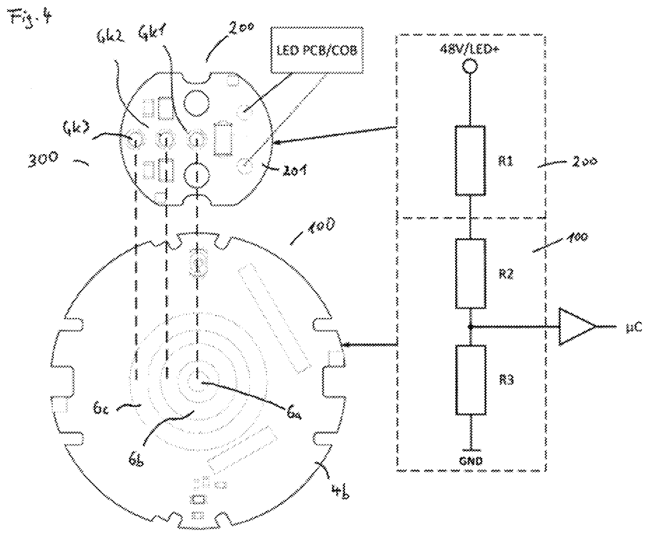

FIG. 4 is a schematic view of an electronic consumer device according to an example embodiment of the present invention.

An electronic consumer device 300 comprising an electronic supply device 100, which can be electrically and mechanically connected to an external electrical conductor device via a surface, is shown, and the electronic consumer device 300 further comprises an electrical consumer 200, which, via the electronic supply device 100, can be electrically connected to the external electrical conductor device and operated.

The first and second external contact 6a and 6b may be supplied with for example 48V via a rectifier. As is shown in the schematic diagram on the right, a voltage of 48V can be applied to the consumer 200, for example an LED, and to its consumer resistor R1. The drawing on the left shows how the counter contacts can be positioned (laterally) in the contact position of the housing of the supply device with the corresponding external contacts, the third counter contact GK3 being electrically connected to a predetermined consumer resistor R1 of the electrical consumer 200, while in the contact position the predetermined consumer resistor R1 can form, together with the circuit board resistors R2 and R3, a voltage divider which, via the first counter contact GK1 and the second counter contact GK2, can provide the electrical consumer 200 with an electrical power/voltage specific to the electrical consumer in question.

The first external contact 6a can be electrically contacted with a first counter contact GK1 of the electrical consumer 200; and the second external contact 6b can be electrically contacted with a second counter contact GK2 of the electrical consumer 200; and the third external contact 6c can be electrically contacted with a third counter contact GK3 of the electrical consumer 200.

The two resistors R2 and R3 of the supply device 100 can be connected to an earth GND, and a control device, such as a microcontroller μC, can be connected between them to generate/receive a dimming signal in the case of a dimmable light (and can take account of the signal from the voltage divider).

Now, because of the arrangement as a voltage divider, the wiring of the resistors R2 and R3, with alternating consumers and thus other consumer resistors R1, can ensure that the power supplied to the consumer can now be matched to its specific power rating without the supply device 100 having to be disconnected from the conductor device and replaced. The differences in the powers may be significant.

The housings of compatible consumers 200 may all have the same dimensioning and configuration of the contact recess and counter contacts. For mounting the housing of the consumer on the surface of the external electrical conductor device, the housing of the consumer may comprise at least one magnet by means of which the housing can be held in place on the surface of the conductor device, for example the wall or ceiling (of a room).

The consumer 200 may comprise an LED chip-on-board device (COB) or another type of light such as an LED PCB.

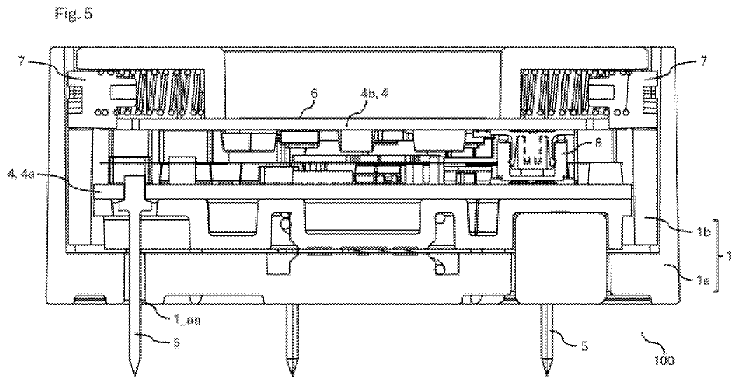

FIG. 5 is a schematic sectional drawing of the electrical circuit board device of the electronic supply device with the first circuit board and second circuit board plugged together.

The electronic supply device 100 comprises a housing 1 having a fastening device and an electrical circuit board device 4, it being possible for the housing 1 to comprise a first housing part 1a with openings 1aa for the pins of the conductor contact device 5. The housing 1 may further comprise a second housing part 1b, into which the circuit board device 4 comprising the first circuit board 4a and the second circuit board 4b can be inserted. The two circuit boards can be electrically and mechanically interconnected by means of the plug device 8. The pins of the conductor contact device 5 can be connected to and fixedly mounted on the first circuit board 4a and, when the housing 1 is in the contact position, as shown in FIG. 5, can be pushed through the openings 1aa in the first housing part 1a. The second housing part 1b may for example be arranged concentric with the first housing part 1a and be slid along its axis of symmetry into an interior region of the first housing part 1a. This may advantageously take place only when the safety mechanism with the associated spring-loaded buttons 7 is released, in other words when the two buttons 7 are pushed into a lateral inner position of the second housing part 1b, as shown in FIG. 5, and do not protrude over or cover the lateral outer edge of the first housing part 1a. When the housing 1 is removed again from the surface of the electrical conductor device (not shown), the pins are no longer held in place in the material of the conductor device or its surface, and a spring can push the two housing parts apart again, and the buttons 7 can spring out laterally into the open position in the transport position of the housing 1 (not shown).

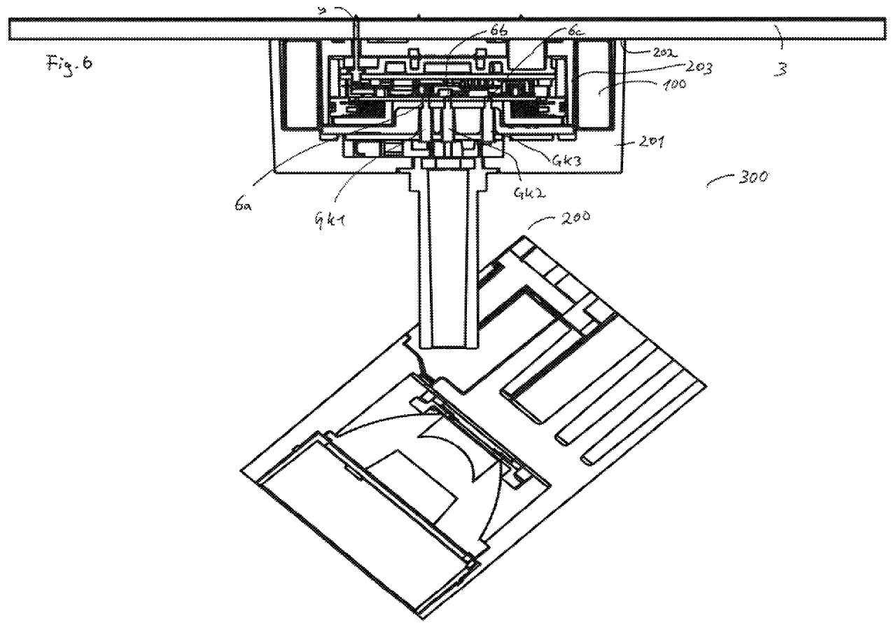

FIG. 6 is a schematic drawing of the electronic consumer device in an external view according to an example embodiment of the present invention.

The electronic consumer device 300 comprises an electronic supply device 100, which can be electrically and mechanically connected by way of a surface to an external electrical conductor device 3, the electronic consumer device 300 further comprising an electrical consumer 200, which, via the electronic supply device 100, can be electrically connected to the external electrical conductor device 3 and operated.

The electrical consumer 200 may comprise a housing 201 with a mounting region 202, via which the electrical consumer 200 can be placed on the surface of the external electrical conductor device 3 or on a surface covering the external electrical conductor device 3 and can be magnetically fixed, and has in the mounting region 202 a contact recess 203, into which the electronic supply device 100 can be inserted, and counter contacts GK1, GK2, GK3 of the electrical consumer 200 extend from the housing 201 of the electrical consumer 200 into the contact recess 203, and, when the electrical consumer 200 is inserted, the counter contacts can be electrically contacted with the respectively associated external contacts 6a, 6b, 6c of the electronic supply device 100.

The contact recess 203 and the housing 1 of the electrical consumer 200 may be circular and, when inserted, be orientated concentrically with one another and be spaced apart in a planar manner (laterally) with respect to the surface, or end flush, it being possible for the housing 201 of the electrical consumer 200 to be rotatable through 360°around the housing 1 of the electronic supply device 100 and about the concentric axis of both housings.

In the above detailed description, various features have been combined in one or more examples for the sake of clarity of illustration. However, it should be appreciated that the above description is merely illustrative and not limiting in nature. It is intended to cover all alternatives, modifications, and equivalents of the various features and example embodiments. In light of the above description, many other examples will be readily and immediately apparent to a person skilled in the art from his expert knowledge.

The example embodiments have been selected and described so as best to illustrate the principles underlying the invention and its possible applications in practice. This enables those skilled in the art to optimally modify and use the invention and its various example embodiments with a view to the intended purpose. In the claims and description, the terms “including” and “having” are used as neutral terminology for the corresponding term “comprising”. Furthermore, use of the terms “a”, “an” and “one” is not intended to exclude in principle the possibility of a plurality of the features and components described in this manner.

### LIST OF REFERENCE SIGNS

1 Housing
1a First housing part
1aa Opening
1b Second housing part
100 Electronic supply device
200 Electrical consumer
201 Housing
202 Mounting region
203 Contact recess
3 External electrical conductor device
300 Electronic consumer device
4 Circuit board device
4a First circuit board
4b Second circuit board
5 Conductor contact device
6 External electrical contact device
6a First external contact
6b Second external contact
6c Third external contact
7 Button/safety mechanism
8, 8b Plug device
AN Antenna path
GK1 First counter contact
GK2 Second counter contact
GK3 Third counter contact
GR Rectifier
HS Hot-plug protector
LT LED driver device
R1 Consumer resistor
R2, R3 Circuit board resistor
SE Control device
VB Bluetooth supply

1. Electronic supply device (100) for electrically connecting an electrical consumer (200), comprising
a housing (1) having a fastening device and an electrical circuit board device (4), the housing (1) being mechanically mountable, in a contact position of the housing, by means of the fastening device, on a surface of an external electrical conductor device (3) or on a surface covering an external electrical conductor device, and the electrical circuit board device (4) being electrically connectable to the external electrical conductor device (3) in the contact position by means of a conductor contact device (5) which is movably arranged in and/or with the housing (1), the electrical circuit board device (4) comprising at least one circuit board resistor (R2, R3);
an external electrical contact device (6) which is arranged on the housing (1) and which can be contacted by counter contacts of the electrical consumer (200), the external electrical contact device (6) further comprising:
a first external contact (6a) which can be electrically contacted with a first counter contact (GK1) of the electrical consumer (200);
a second external contact (6b) which can be electrically contacted with a second counter contact (GK2) of the electrical consumer (200); and
a third external contact (6c) which can be electrically contacted with a third counter contact (GK3) of the electrical consumer (200), the third counter contact (GK3) being in an electrical connection with a predetermined consumer resistor (R1) of the electrical consumer (200), the predetermined consumer resistor (R1), in the contact position, forming together with the at least one circuit board resistor (R2, R3) a voltage divider through which an electrical power specific to the relevant electrical consumer (200) can be provided to the electrical consumer (200) via the first counter contact (GK1) and via the second counter contact (GK2).

2. Electronic supply device (100) according to claim 1,
characterised in that the first external contact (6a) and/or the second external contact (6b) and/or the third external contact (6c) are formed as a ring contact.

3. Electronic supply device (100) according to claim 2,
characterised in that the first external contact (6a) forms a circular surface, and the second external contact (6b) and the third external contact (6c) extend around the first external contact (6a) as spaced-apart concentric annular surfaces.

4. Electronic supply device (100) according to claim 1,
characterised in that the conductor contact device (5) comprises at least two pins as electrical contacts, which are extended from the housing (1) in its contact position and can be brought into mechanical and electrical contact with the surface of the external electrical conductor device (3) or with the surface covering the external electrical conductor device.

5. Electronic supply device (100) according to claim 4,
characterised in that the pins can penetrate the surface of the external electrical conductor device (3) or the surface covering the external electrical conductor device, and different pins can be contacted with electrical conductors of different polarity.

6. Electronic supply device (100) according to claim 1,
characterised in that the external electrical contact device (6) is arranged on an externally accessible upper face of the housing (1), which is opposite a lower face of the housing (1), the fastening device being arranged and/or the conductor contact device (5) being extendable on the lower face, and/or in that the housing (1) with the fastening device is set up to be arranged on a planar surface which forms or covers the external electrical conductor device (3), and/or in that the electronic supply device (100) comprises a signal light which is arranged on the housing (1) and via which electrical contact with the external electrical conductor device (3) can be indicated.

7. Electronic supply device (100) according to claim 1,
characterised in that the electronic supply device (100) and the circuit board device (4) comprise a rectifier (GR), by means of which a current received from the external electrical conductor device (3) via the conductor contact device (5) can be applied to the first external contact (6a) and the second external contact (6b) with different polarities from one another.

8. Electronic supply device (100) according to claim 7,
characterised in that the electrical circuit board device (4) comprises at least two flat circuit boards, which are spaced apart from one another and extend centred and parallel along an axis and are interconnected via a contact device or plug device (8).

9. Electronic supply device (100) according to claim 8,
characterised in that the three external contacts (6a, 6b, 6c) are arranged on a face of the second circuit board facing away from the first circuit board.

10. Electronic supply device (100) according to claim 1,
characterised in that the electrical circuit board device (4) comprises a control device (SE), which can receive and interpret a wirelessly transmitted control signal and via which operation of the electrical consumer (200) can be controlled, and/or in that the electrical circuit board device (4) comprises an LED driver device (LT) by means of which the specific electrical power can be detected and provided, and/or in that the electrical circuit board device (4) comprises a hot-plug protector (HS), and/or in that the circuit board resistor (R2, R3) comprises a first resistor (R2) and a second resistor (R3) which, in contact with the predetermined consumer resistor (R1), form a voltage divider.

11. Electronic supply device (100) according to claim 9, wherein the rectifier (GR) is arranged on a face of the first circuit board facing the second circuit board.

12. Electronic consumer device (300) comprising an electronic supply device (100) according to claim 1, which can be electrically and mechanically connected via a surface to an external electrical conductor device (3), the electronic consumer device (300) further comprising an electrical consumer (200), which, via the electronic supply device (100), can be electrically connected to the external electrical conductor device (3) and operated.

13. Electronic consumer device (300) according to claim 12,
characterised in that the electrical consumer (200) comprises a housing (201) with a mounting region (202), via which the electrical consumer (200) can be placed and magnetically fixed on the surface of the external electrical conductor device (3) or on a surface covering the external electrical conductor device (3), and has in the mounting region (202) a contact recess (203) into which the electronic supply device (100) can be inserted, and counter contacts (GK1, GK2, GK3) of the electrical consumer (200) extend from the housing (201) of the electrical consumer (200) into the contact recess (203), and, when the electrical consumer (200) is inserted, the counter contacts can be electrically contacted with the respectively associated external contacts (6a, 6b, 6c) of the electronic supply device (100).

14. Electronic consumer device (300) according to claim 13,
characterised in that the contact recess (203) and the housing (1) of the electrical consumer (200) are circular and, when inserted, are orientated concentrically with one another and spaced apart in a planar manner with respect to the surface, the housing (201) of the electrical consumer (200) being rotatable through 360° around the housing (1) of the electronic supply device (100) and about the concentric axis, and/or in that the counter contacts (GK1, GK2, GK3) of the electrical consumer (200) comprise spring-loaded pin contacts.

15. Electronic consumer device (300) according to claim 12,
characterised in that the electrical consumer (200) comprises a dimmable or non-dimmable light, and/or in that the electrical consumer (200) comprises a charger or a display device or a power source for a further consumer.
